(19) United States
(12) Patent Application Publication
(10) Pub. No.: US 2026/0240034 A1
(43) Pub. Date: Aug. 13, 2026

(54) SEMICONDUCTOR PACKAGE AND A METHOD FOR FORMING THE SAME

(71) Applicant: JCET STATS ChipPAC Korea Limited, Incheon (KR)

(72) Inventors: WonSang RHEE, Incheon (KR); JoonSung PARK, Incheon (KR); HyeonChul LEE, Seoul (KR)

(21) Appl. No.: 19/536,135

(22) Filed: Feb. 10, 2026

(30) Foreign Application Priority Data
Feb. 11, 2025 (CN) 202510149585.1

(51) Int. Cl. H10W 74/10

(52) U.S. Cl. CPC H10W 74/117

(57) ABSTRACT

A semiconductor package comprises: a substrate having a front surface, a back surface and lateral surfaces extending between the front surface and the back surface, wherein the substrate comprises embedded conductive wires; one or more electronic components mounted on the front surface of the substrate; a mold cap formed on the front surface of the substrate to encapsulate the one or more electronic components; and a set of lateral conductive pads formed on one of the lateral surfaces of the substrate and across an entire thickness of the substrate, wherein each of the set of lateral conductive pads extends from the substrate to the mold cap to cover a portion of a thickness of the mold cap, and wherein the set of lateral conductive pads are electrically coupled to the embedded conductive wires of the substrate.

### TECHNICAL FIELD

The present application generally relates to semiconductor technologies, and more particularly, to a semiconductor package and a method for forming a semiconductor package.

### BACKGROUND OF THE INVENTION

The semiconductor industry is constantly faced with complex integration challenges as consumers want their electronics to be smaller, faster and higher performance with more and more functionalities packed into a single device. In some semiconductor packages, a Package-in-Package (PiP) or Package-on-Package (PoP) process is utilized to combine two or more integrated circuit (IC) packages together as an integrated device. The PiP or PoP devices can more efficiently use space, and reduce lengths of signal paths between the packages. In a typical PiP or PoP device, one or more semiconductor chips and Input/Output (IO) connections may be mounted onto a single substrate.

However, it is noted that the number of semiconductor chips required to be mounted on a substrate increases significantly and IOs which may take a significant area of the device may limit the deployment of these semiconductor chips on the substrate. That is, the IOs such as copper (Cu) pins or solder balls might limit the flexibility and number of IOs due to space constraints.

Therefore, a need exists for further improvement to semiconductor packages or devices with a large quantity of semiconductor chips and IOs.

### SUMMARY OF THE INVENTION

An objective of the present application is to provide a semiconductor package with improved flexibility and reliability in mounting.

According to an aspect of the present application, a semiconductor package is disclosed. The semiconductor package comprises: a substrate having a front surface, a back surface and lateral surfaces extending between the front surface and the back surface, wherein the substrate comprises embedded conductive wires; one or more electronic components mounted on the front surface of the substrate; a mold cap formed on the front surface of the substrate to encapsulate the one or more electronic components; and a set of lateral conductive pads formed on one of the lateral surfaces of the substrate and across an entire thickness of the substrate, wherein each of the set of lateral conductive pads extends from the substrate to the mold cap to cover a portion of a thickness of the mold cap, and wherein the set of lateral conductive pads are electrically coupled to the embedded conductive wires of the substrate.

According to another aspect of the present application, a method for forming a semiconductor package is provided. The method comprises: providing a molded semiconductor package having a substrate and a mold cap formed on a front surface of the substrate and encapsulating one or more electronic components on the substrate; applying a releasable mask onto a back surface of the substrate; forming one or more sets of holes in the molded semiconductor package through the releasable mask, such that the sets of holes pass through the substrate and extend into the mold cap; depositing a conductive material on the releasable mask to form a set of conductive vias in each set of the sets of holes; removing the releasable mask from the substrate; and separating the semiconductor package into units along each set of the sets of conductive vias to expose the set of conductive vias from a lateral surface of one of the units as a set of conductive pads.

According to a further aspect of the present application, a semiconductor package assembly is disclosed. The semiconductor package assembly comprises: a base substrate; a semiconductor package mounted on and electrically coupled to the base substrate, wherein the semiconductor package comprises: a substrate having a front surface, a back surface and lateral surfaces extending between the front surface and the back surface, wherein the substrate comprises embedded conductive wires; one or more electronic components mounted on the front surface of the substrate; a mold cap formed on the front surface of the substrate to encapsulate the one or more electronic components; and a set of lateral conductive pads formed on one of the lateral surfaces of the substrate and across an entire thickness of the substrate, wherein each of the set of lateral conductive pads extends from the substrate to the mold cap to cover a portion of a thickness of the mold cap, and wherein the set of lateral conductive pads are electrically coupled to the embedded conductive wires of the substrate; and wherein the semiconductor package is mounted on the base substrate via the set of lateral conductive pads.

According to a further aspect of the present application, a semiconductor package assembly is disclosed. The semiconductor package assembly comprises: a base substrate; a first semiconductor package having a first set of conductive pads and a second set of conductive pads on a first lateral surface and a second lateral surface of the first semiconductor package, respectively, wherein the first and second sets of conductive pads are electrically coupled with each other; wherein the first semiconductor package is mounted on the base substrate via the first set of conductive pads; a second semiconductor package having a third set of conductive pads and a fourth set of conductive pads on a third lateral surface and a fourth lateral surface of the second semiconductor package, respectively, wherein the third and fourth sets of conductive pads are electrically coupled with each other; wherein the second semiconductor package is mounted on the first semiconductor package via the second and third sets of conductive pads; and wherein the first and second semiconductor packages stand vertically with respect to the base substrate.

According to another aspect of the present application, a method for forming a semiconductor package assembly is provided. The method comprises: providing a base substrate; mounting vertically onto the base substrate a first semiconductor package having a first set of conductive pads and a second set of conductive pads on a first lateral surface and a second lateral surface of the first semiconductor package, respectively, to electrically couple the base substrate with the first semiconductor package via the first set of conductive pads, wherein the first and second sets of conductive pads are electrically coupled with each other; and mounting vertically onto the first semiconductor package a second semiconductor package having a third set of conductive pads and a fourth set of conductive pads on a third lateral surface and a fourth lateral surface of the second semiconductor package, respectively, to electrically couple the second semiconductor package with the first semiconductor package via the second and third sets of conductive pads, wherein the third and fourth sets of conductive pads are electrically coupled with each other.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates a semiconductor package according to an embodiment of the present application.

FIG. 1B illustrates a side view of the semiconductor package shown in FIG. 1A.

FIGS. 2A to 2E illustrate a method for forming a semiconductor package according to an embodiment of the present application.

FIG. 3 illustrates a semiconductor package assembly according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, conventional semiconductor packages may not be mounted on a circuit board or other similar bases flexibility, due to their IOs such as Cu pins or solder balls which may limit the deployment of semiconductor chips in the semiconductor packages during manufacturing. To address this issue, the inventors of the present application have conceived an invention of forming sets of conductive pads at lateral surfaces of the semiconductor packages, which can help remove constraints on the number and size of IOs, thus leaving more space for mounting semiconductor chips on substrates of the semiconductor packages. This method of forming sets of lateral conductive pads not only increases the number of available IOs but also allows for setting the size and shape of the IOs as needed to accommodate various application requirements during a design stage of such semiconductor packages.

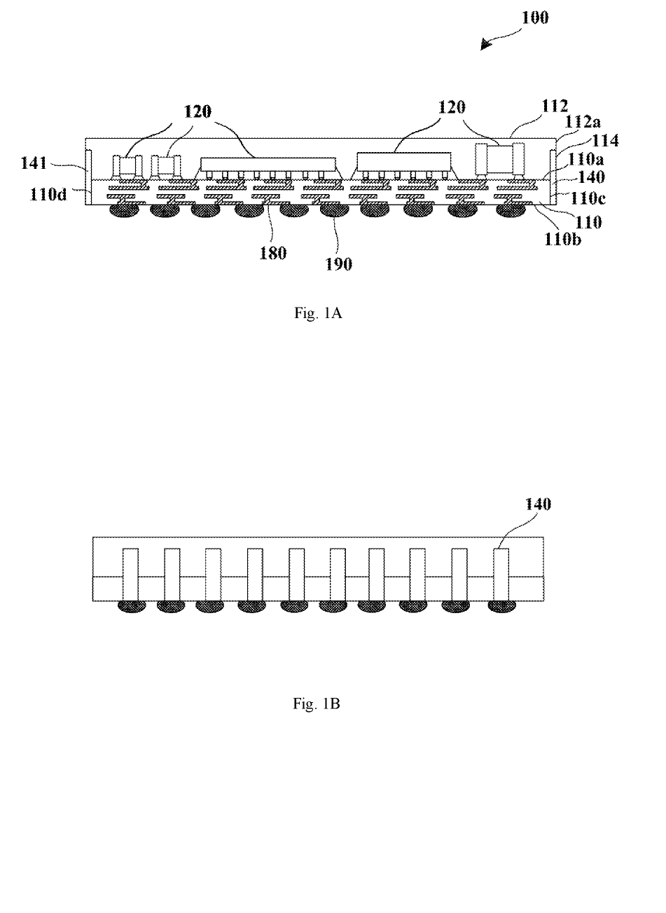

FIG. 1A and FIG. 1B illustrate a semiconductor package 100 according to an embodiment of the present application.

As shown in FIG. 1A, the semiconductor package 100 may include a substrate 110, and one or more electronic components 120 mounted on the substrate 110. In some embodiments, each of the electronic component 120 may be a semiconductor die or a smaller semiconductor package which may be mounted on a front surface of the substrate 110 via solder bumps or similar structures, or can be any other suitable electronic components such as capacitors, resistors, inductors, etc. A mold cap 112 is formed on the front surface of the substrate 110 to encapsulate the one or more electronic components 120. In some embodiments, the mold cap 112 may expose respective front surfaces of one or more of the electronic components 120, i.e., only lateral surfaces of the electronic components 120 are covered by the mold cap 112. For example, the mold cap 112 may be formed with an excess amount of a molding material over the electronic components 120, which may later be attenuated (e.g., etched) to some extent to expose the front surfaces of a portion or all of the electronic components 120. However, it is not required that the electronic components 120 are exposed from the mold cap 112. For example, in the embodiment shown in FIG. 1A, all the electronic components 120 are fully covered by the mold cap 112 which provides for better protection from the external environment and damages. In some embodiments, the mold cap 112 may be made, partially or in all, of a polymer composite material such as epoxy resin with filler, epoxy acrylate with filler, or polymer with proper filler.

Still referring to FIG. 1A, solder bumps 190 may be mounted onto a back surface 110b of the substrate 110, which is opposite to the front surface 110a, to allow the entire semiconductor package 100 to be mounted on or connected to an external device when needed. The substrate 110 has embedded conductive wires 180, for example, the substrate 110 may include a printed circuit board (PCB), a carrier substrate, a semiconductor substrate with electrical interconnections, a ceramic substrate, a laminate interposer, a strip interposer, a lead frame, or other suitable substrates. The substrate 110 may include any structure on or in which an integrated circuit system can be fabricated. In some examples, the substrate 110 may include redistribution structures having one or more dielectric layers and one or more conductive layers between and through dielectric layers. The conductive layers may define pads, traces and plugs through which electrical signals or voltages can be distributed horizontally and vertically across the redistribution structures. The solder bumps 190 may be electrically connected to the conductive structures of the substrate 110, and thus, connected to the electronic components on the substrate 110. It can be appreciated that the solder bumps 190 are optional, and may not be included in the semiconductor package 100 in some embodiments of the present application, for example, when other structures provide connectivity for the semiconductor package 100 to an external device, as will be elaborated below.

The one or more electronic components 120 may include any of a variety of types of semiconductor dice, semiconductor packages, or discrete devices. For example, the one or more electronic components 120 may include a logic chip such as a central processing unit (CPU) or a graphics processing unit (GPU), a memory device such as a high bandwidth memory (HBM), a digital signal processor (DSP), a radiofrequency (RF) circuit, a wireless baseband system-on-chip (SoC) processor, a sensor, an application specific integrated circuit, etc. The one or more electronic components 120 may be passive components such as resistors, capacitors, inductors, switches, or any other suitable electronic devices. The one or more electronic components 120 are mounted on the front surface 110a of the substrate 110 where can provide support and connectivity for electronic components and devices.

Still referring to FIG. 1A, as mentioned above, certain lateral conductive structures may be formed outermost the entire semiconductor package 100, to provide connectivity to the external device. In particular, a first set of lateral conductive pads 140 may be formed on a first lateral surface 110c of the substrate 110, and a second set of lateral conductive pads 141 may be formed on a second lateral surface 110d of the substrate 110. In the embodiment, the first lateral surface 110c is opposite to the second lateral surface 110d, with relative to the semiconductor package 100 which can be shaped as a cuboid, for example. Each conductive pad of the first and second sets of lateral conductive pads extends across an entire thickness of the substrate 110, and extends further from the substrate 110 to the mold cap 112, covering a portion of the thickness of the mold cap 112. However, the conductive pads may not extend across an entire thickness of the mold cap 112. Each conductive pad may be electrically connected to the respective conductive wires of the substrate 110 so as to be further connected to the electronic components 120 mounted on the substrate 110. The design of the lateral conductive pads offers a number of electrical connection points or terminals without substantially increasing the size of the semiconductor package 100. It can be appreciated that the multiple lateral conductive pads serving as electrical connection points or terminals can be electrically isolated from each other, i.e., be electrically coupled to the internal electronic components or other positions of the semiconductor package 100 via respective embedded wires, to realize separated signal or electrical paths.

As shown in FIG. 1B, which is a side view of the semiconductor package 100, the lateral conductive pads may be rectangularly shaped, allowing easy adjustment of the number and positioning of the lateral conductive pads according to specific applications to optimize the performance of semiconductor package 100. Moreover, the lateral conductive pads at the lateral sides of the semiconductor package 100 can mitigate the risk of failures due to overloading on the top surface of the substrate 110 and thus improving the reliability of the semiconductor package 100. It should be noted that although in the embodiment shown in FIG. 1A and FIG. 1B, the two sets of lateral conductive pads are positioned at two opposite sides of the semiconductor package 100, while in some alternative embodiments, the two sets of lateral conductive pads may be positioned at two adjacent sides of the semiconductor package 100, or more sets of lateral conductive pads may be formed at three or four lateral sides of the semiconductor package 100 in a manner similar as the sets of lateral conductive pads 140 and 141 shown in FIGS. 1A and 1B.

In some embodiments, the second set of lateral conductive pads 141 are electrically coupled to the first set of lateral conductive pads 140 through the embedded conductive wires 180 of the substrate 110. In this embodiment, the first and second set of lateral conductive pads 140 and 141 are positioned at opposite sides of the substrate 110 to provide across-the-substrate connectivity, facilitating a balanced distribution of electrical connections and thermal management across the semiconductor package 100. However, it can be understood that the deployment of these lateral conductive pads is not limited to this configuration. In alternative embodiments, the lateral conductive pads could be arranged in various patterns or positions on the lateral surface(s) of the substrate 110 and the lateral surfaces(s) of the mold cap 112 adjacent thereto, to accommodate different design requirements or to optimize specific functionalities. It can be appreciated that, when talking about the second set of lateral conductive pads 141 are electrically coupled to the first set of lateral conductive pads 140, one or more lateral conductive pads of the first set of lateral conductive pads 140 can be electrically coupled to one of the second set of lateral conductive pads 141, to realize separated signal and electrical paths; it is not required that all the lateral conductive pads are electrically coupled together; and optionally, some lateral conductive pads can also be electrically coupled to other electronic components of the semiconductor package 100, to the solder bumps 190 on the back surface of the substrate 110, or to any other suitable positions or structures of the semiconductor package 100.

Still referring to FIG. 1A and FIG. 1B, the mold cap 112 features a stepped lateral surface 112a that is adjacent to the first lateral surface 110c of the substrate, which is designed to accommodate and embed the first set of lateral conductive pads 140. An outer portion (i.e., the upper portion in the direction of FIGS. 1A and 1B) of the stepped lateral surface 112a is aligned with the outer surfaces of the first set of lateral conductive pads 140, to integrate the first set of lateral conductive pads 140 into the semiconductor package and create a flat surface 114 at the lateral side of the semiconductor package 100. The flat lateral surface of the semiconductor package 100 facilitates integrated packaging techniques like 3D stacking and chiplet integration. The lateral conductive pads can serve as interfaces for vertical interconnects between stacked dice, enabling the creation of three-dimensional integrated circuits (3D ICs) with enhanced functionality and performance, which will be described below in more details. Moreover, the lateral conductive pads serve not only for electrical connections but also as thermal pathways. In particular, the lateral conductive pads, which are generally formed of thermal conductive materials such as copper, can effectively dissipate heat generated within the semiconductor package 100 to the external environment, along with the embedded wires distributed in the substrate 100.

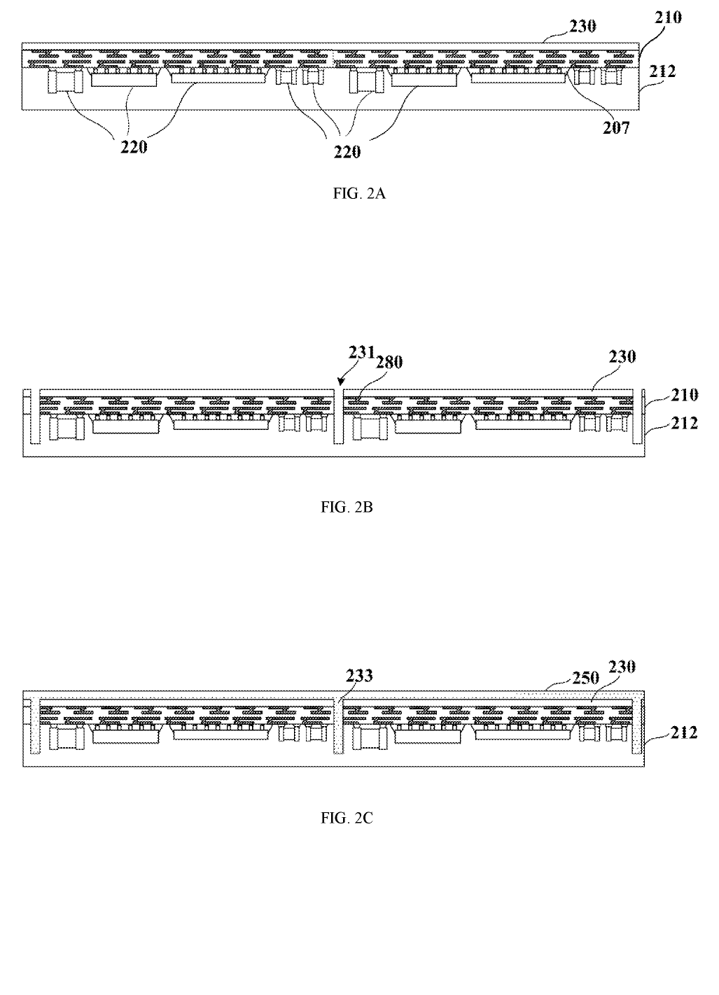

FIGS. 2A to 2E illustrate a method for forming a semiconductor package according to an embodiment of the present application. In some examples, the method can be used to make large scale semiconductor packages which may have multiple semiconductor chips integrated therein.

As shown in FIG. 2A, a substrate 210 is provided with one or more electronic components 220 mounted onto a front surface of the substrate 210 via solder bumps, for example. In the embodiment, the substrate 210 is a substrate strip which includes a plurality of units having the same layout and overall structure, which, after the packaging processing, can be singulated into a plurality of pieces. It can be appreciated that the following processes are described with reference to one of the same units of the substrate 210. Thus, similar processes can be implemented to a portion or all the units of the substrate 210. Also, it can be appreciated that in some embodiment, the substrate 210 may have only one unit, which thus does not need singulation but may need similar sawing process to remove undesired marginal portions, for example. An underfill material 207 may be filled between the electronic components 220 and the substrate 210 and around the solder bumps under the electronic components 220, to enhance the attachment of the electronic components 220 to the substrate 210. A mold cap 212 may be formed on the substrate 210 to encapsulate the electronic components 220, transforming the substrate 210 and the electronic components 220 into a molded semiconductor package. For example, the mold cap 212 may be formed using an injection molding process or a compression molding process. In some other embodiments, the mold cap 212 may be formed using paste printing, transfer molding, liquid encapsulant molding, vacuum lamination, spin coating, or any other suitable process.

A releasable mask 230 is applied onto a back surface of the substrate 210, which can be serve as a deposition mask in a subsequent process, which will be elaborated below. The releasable mask 230 can be made from a photosensitive material which may exhibit different adhesiveness or strength before and after exposure to light radiation, or may be made from an adhesive tape, providing temporary protection for the mold cap 212 during the subsequent process.

Next, as shown in FIG. 2B, one or more sets of holes 231 are formed in the molded semiconductor package through the releasable mask 230, for example, by drilling. In some embodiments, each set of holes 231 may be formed along a straight line when view from top of the substrate 200. Drilling by laser ablation or using other methods ensures that the sets of holes 231 penetrate through the substrate 210 and extend into the mold cap 212. The laser ablation process is operated to remove the entire thickness of the substrate 210 and a portion of the thickness of the mold cap 212 at the locations where the sets of holes are drilled to expose embedded conductive wires 280 within the substrate 210 from the lateral side of the substrate 210. Moreover, it can be appreciated that the number and shape of the sets of holes can vary from the example as illustrated in FIG. 2B. For example, the sets of holes can be configured to suit the specific requirements of the semiconductor package which allows to accommodate different packaging densities, electrical connection schemes, and thermal management strategies. The shape of the holes can also be adjusted to optimize the interaction with the conductive wires and to enhance the mechanical stability of the semiconductor package.

Still referring to FIG. 2B, the process of drilling the sets of holes 231 in the molded semiconductor package requires meticulous precision to ensure that they can reach an exact depth within the substrate 210 where the embedded conductive wires 280 are located. If the sets of holes are drilled insufficiently and do not reach the desired depth, the embedded conductive wires 280 may not be adequately exposed from the holes. In contrast, drilling the holes too deep may pose the risk of damaging the embedded conductive wires 280 or even the substrate 210 itself (e.g., drill through the entire thickness of the substrate 210). In some embodiments, each of the holes can be precisely drilled to a uniform depth to ensure consistency across all electrical connections to be formed to provide a reliable and uniform interface. However, the depth of each hole can also be designed individually to accommodate specific packaging requirements. Furthermore, achieving precise control over the drilling process minimizes the likelihood of introducing mechanical stress into the substrate 210, which could otherwise result in warping or cracking, potentially compromising the overall reliability of the semiconductor package. In some embodiments, the depth control of the drilling process can be implemented by adjusting a time for the laser ablation process, and in some alternative embodiments, a real-time feedback mechanism (e.g., a laser depth measurement mechanism) may be used to control the depth of the holes.

Next, as shown in FIG. 2C, a conductive material 250 is deposited on the releasable mask 230 to form a set of conductive vias 233 in each set of the holes. The formation of the set of conductive vias 233 can be achieved through various methods, including sputtering, electroplating, or chemical vapor deposition. The material of conductive material may possess excellent electrical conductivity, chemical stability, and mechanical strength to ensure the durability and reliability of the set of conductive vias 233. Materials suitable for the set of conductive vias 233 can include copper (Cu), which is favored for its high conductivity and ductility, or tungsten (W), which is valued for its robustness and resistance to corrosion. Other materials such as silver (Ag) or gold (Au) may also be used in specific applications where their unique properties, such as lower contact resistance or higher resistance to oxidation.

As shown in FIG. 2D, once the conductive material has been successfully deposited on the releasable mask and into the sets of holes, and the set of conductive vias 233 have been formed, the releasable mask can be removed from the substrate 210 to expose the substrate 210.

This removal is typically executed using a solvent or a lift-off process that is specifically designed to dissolve or weaken the adhesive properties of the releasable mask without causing damage to the underlying substrate or the newly formed sets of conductive vias. In some embodiments where the releasable mask is made from a tape, a peel-off process may be used to remove the mask. In some other embodiments, an etching process or any other suitable processes may be used to remove the releasable mask.

Referring to FIG. 2E, the semiconductor package is separated into a plurality of units or pieces along each set of conductive vias, which may be arranged along a straight line, to expose the set of conductive vias from a lateral surface of one of the units as a set of conductive pads 240. For example, in the embodiment shown FIG. 2E, one semiconductor package unit may have two sets of conductive pads 240 which are transformed from two sets of conductive vias at two lateral sides of the semiconductor package unit. The separation or singulation process may be implemented by cutting using a sawing tool, for example. By placing the cuts along the respective sets of conductive vias, the semiconductor package can be separated into distinct units each including a portion of conductive vias. In particular, a saw or cut street region may have a width smaller than a diameter of the conductive vias, and thus each conductive via can be separated into two parts respectively attached to two package units, even if some material of the conductive via may be consumed during the cutting process.

In the process of separating the semiconductor package into individual units, it is not required to evenly separate each one of the sets of conductive vias. The separation can be operated based on the specific requirements of the design and the desired functionality of each unit. This flexibility allows for a more efficient distribution of the set of conductive pads 240, which can enhance the electrical performance and thermal management of the semiconductor package. As aforementioned, the separation may be achieved through various methods, including laser cutting, mechanical sawing, dicing, chemical etching, thermal separation, and plasma etching. These methods allow for precise control over the depth and location of the cuts, ensuring clean and accurate separation. It can be appreciated that the forming of the conductive pads can be implemented during the singulation of the substrate, which reduces the cost of manufacturing.

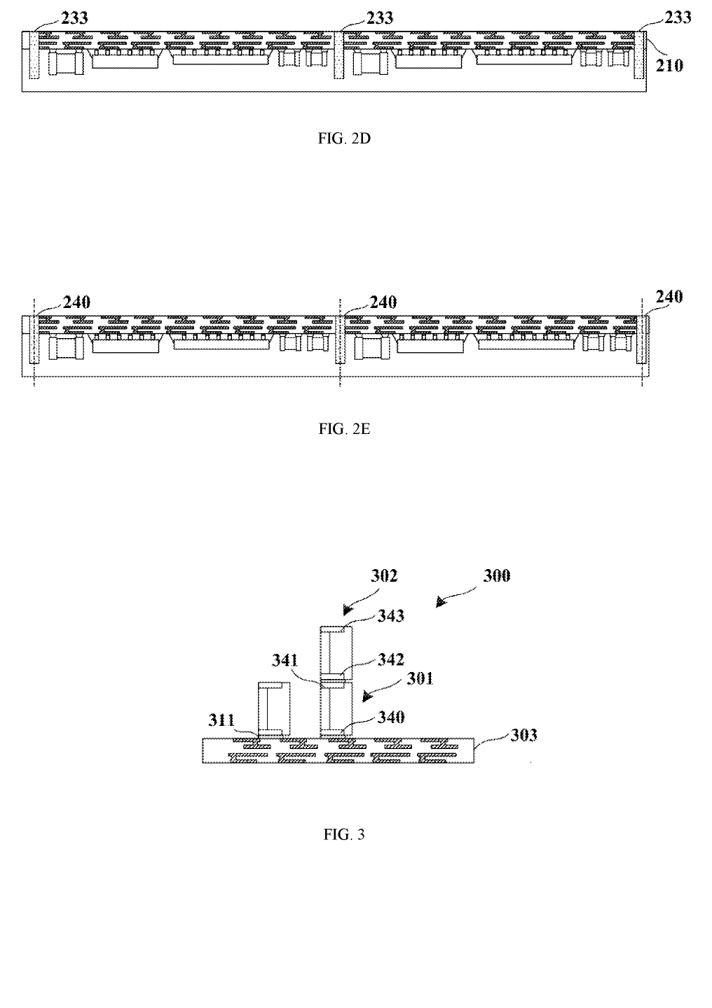

As aforementioned, the lateral conductive pads may be formed at two opposite sides of a semiconductor package. In that configuration, multiple semiconductor packages may be stacked together on a base substrate in a vertical arrangement, rather than in a horizontal arrangement. FIG. 3 illustrates a semiconductor package assembly 300 according to an embodiment of the present application.

As shown in FIG. 3, the semiconductor package assembly 300 has a first semiconductor package 301 mounted on a base substrate 303 via a first set of lateral conductive pads 340. The first set of lateral conductive pads 340 provide for electrical and mechanical connections between the first semiconductor package 301 and the base substrate 303. In some embodiments, the first semiconductor package 301 may be mounted on the base substrate 303 via a set of solder bumps. Besides the first set of lateral conductive pads 340, a second set of lateral conductive pads 341 are formed topmost the first semiconductor package 301, which provide anchors for further attachment of one or more additional semiconductor packages.

In particular, a second semiconductor package 302 is vertically stacked atop the first semiconductor package 301 by aligning a third set of lateral conductive pads 342 of the second semiconductor package 302 with the second set of lateral conductive pads 341 of the first semiconductor package 301. These two sets of lateral conductive pads 341 and 342 can form electrical and mechanical connection between the two semiconductor packages 301 and 302. In some embodiments, the adjacent sets of lateral conductive pads may be connected together via solder bumps or in any other suitable manners. Although it is shown in FIG. 3 each of the first and second semiconductor packages 302 and 304 includes two sets of lateral conductive pads, more sets of lateral conductive pads may be formed at one or both of the other two lateral sides of each of the semiconductor package 302 and 304. In this way, the package stack can not only extend vertically by stacking more packages, but also extend horizontally by connecting two or more packages side by side on the base substrate in a manner of building blocks.

It should be noted that although two semiconductor packages are illustrated in FIG. 3 as an example, more semiconductor packages may be integrated within the semiconductor package assembly 300, as desired. For example, three or more semiconductor packages may be stacked together via their respective lateral conductive pads respectively. The strategic positioning of the lateral conductive pads substantially optimizes signal transmission and power distribution. The direct contact between the lateral conductive pads results in lower resistance and impedance levels to achieve faster signal propagation and reduce signal degradation or loss.

The vertical stacking of the semiconductor package assembly 300 is a strategic approach to maximize the functionality and performance of the semiconductor assembly which allows for the integration of multiple semiconductor packages in a compact form factor, enhancing the overall functionality of the assembly. It also contributes to the efficient management of thermal properties within the assembly because set of lateral conductive pads provide more direct pathways for heat to escape from the package assembly, which realizes better heat dissipation compared to traditional horizontal configurations.

A method for forming the semiconductor package assembly shown in FIG. 3 is provided according to an embodiment of the present application. As shown in FIG. 3, the base substrate 303 may be served as a base layer for the entire semiconductor package assembly. Next, the first semiconductor package 301 featuring two opposite sets of conductive pads 340 and 341 on its first and second lateral surfaces is vertically mounted onto the base substrate 303. The first conductive pads 340 and the second conductive pads 341 are electrically coupled with each other, e.g., through conductive wires within its substrate, and the base substrate 303 is electrically coupled with the first semiconductor package 301 via the first set of conductive pads 340. Following this, the second semiconductor package 302, which similarly has two sets of conductive pads, i.e., the third set of conductive pads 342 and the fourth set of conductive pads 343 on its two opposite lateral surfaces, is vertically mounted onto the first semiconductor package 301. The second semiconductor package 302 is electrically coupled with the first semiconductor package 301 via the second and third sets of conductive pads. Similar to the first semiconductor package 301, the third and fourth sets of conductive pads are electrically coupled with each other. It can be appreciated that there may be solder materials or thermal interface materials (TIM) layers 311 between the semiconductor packages 301 and 302 and the base substrate 303 to ensure secure and stable electrical connection.

Still referring to FIG. 3, the lateral surface of the first semiconductor package 301 is flat because the first set of conductive pads 340 is embedded within the first semiconductor package 301, instead of protruding from the lateral surface of the substrate and the mold cap of the first semiconductor package 301. When the first semiconductor package 301 is mounted on a base substrate which has a generally flat surface in the manner shown in FIG. 3, the flat lateral surface of the first semiconductor package 301 can eliminate an undesired gap from the base substrate, as well as avoid tilting with relative to the base substrate, thereby improving the connection between the first semiconductor package 301 and the base substrate and allowing vertically stacking more packages on the first semiconductor package (e.g. the second semiconductor package on the first semiconductor package) and thus on the base substrate. The same also applies to the second semiconductor package and other semiconductor packages mounted on the base substrate, i.e., with the flat lateral surfaces preferred.

The discussion herein includes numerous illustrative figures that show various portions of a semiconductor package and a method for forming such semiconductor package. For illustrative clarity, such figures do not show all aspects of each example semiconductor package. Any of the example packages provided herein may share any or all characteristics with any or all other packages provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package, comprising:
a substrate having a front surface, a back surface and lateral surfaces extending between the front surface and the back surface, wherein the substrate comprises embedded conductive wires;
one or more electronic components mounted on the front surface of the substrate;
a mold cap formed on the front surface of the substrate to encapsulate the one or more electronic components; and
a set of lateral conductive pads formed on one of the lateral surfaces of the substrate and across an entire thickness of the substrate, wherein each of the set of lateral conductive pads extends from the substrate to the mold cap to cover a portion of a thickness of the mold cap, and wherein the set of lateral conductive pads are electrically coupled to the embedded conductive wires of the substrate.

2. The semiconductor package of claim 1, wherein the set of lateral conductive pads is a first set of lateral conductive pads formed on a first lateral surface, the semiconductor package further comprises a second set of lateral conductive pads formed on a second lateral surface of the substrate, each of the second set of lateral conductive pads extends from the substrate to the mold cap to cover a portion of the thickness of the mold cap, and the second set of lateral conductive pads are electrically coupled to the first set of lateral conductive pads through the embedded conductive wires of the substrate.

3. The semiconductor package of claim 2, wherein the first lateral surface is opposite to the second lateral surface relative to the substrate.

4. The semiconductor package of claim 2, wherein the substrate has a rectangular layout.

5. The semiconductor package of claim 1, wherein the mold cap has a stepped lateral surface adjacent to the lateral surface of the substrate formed with the set of lateral conductive pads to receive the set of lateral conductive pads and to form a flat surface with the set of lateral conductive pads.

6. A semiconductor package assembly, comprising:
a base substrate;
a semiconductor package mounted on and electrically coupled to the base substrate, wherein the semiconductor package comprises:
a substrate having a front surface, a back surface and lateral surfaces extending between the front surface and the back surface, wherein the substrate comprises embedded conductive wires;
one or more electronic components mounted on the front surface of the substrate;
a mold cap formed on the front surface of the substrate to encapsulate the one or more electronic components; and
a set of lateral conductive pads formed on one of the lateral surfaces of the substrate and across an entire thickness of the substrate, wherein each of the set of lateral conductive pads extends from the substrate to the mold cap to cover a portion of a thickness of the mold cap, and wherein the set of lateral conductive pads are electrically coupled to the embedded conductive wires of the substrate; and
wherein the semiconductor package is mounted on the base substrate via the set of lateral conductive pads.

7. The semiconductor package assembly of claim 6, wherein the mold cap has a stepped lateral surface adjacent to the lateral surface of the substrate formed with the set of lateral conductive pads to receive the set of lateral conductive pads and to form a flat surface with the set of lateral conductive pads.

8. The semiconductor package assembly of claim 6, wherein the set of lateral conductive pads is a first set of lateral conductive pads formed on a first lateral surface, the semiconductor package further comprises a second set of lateral conductive pads formed on a second lateral surface of the substrate opposite to the first lateral surface, each of the second set of lateral conductive pads extends from the substrate to the mold cap to cover a portion of the thickness of the mold cap, and the second set of lateral conductive pads are electrically coupled to the first set of lateral conductive pads through the embedded conductive wires of the substrate.

9. The semiconductor package assembly of claim 8, wherein the substrate has a rectangular layout.

10. The semiconductor package assembly of claim 9, wherein the semiconductor package is a first semiconductor package, and the semiconductor package assembly further comprises a second semiconductor package mounted on and electrically coupled to the first semiconductor package, wherein the second semiconductor package comprises:
a substrate having a front surface, a back surface and lateral surfaces extending between the front surface and the back surface, wherein the substrate comprises embedded conductive wires;
one or more electronic components mounted on the front surface of the substrate;
a mold cap formed on the front surface of the substrate to encapsulate the one or more electronic components; and
a set of lateral conductive pads formed on one of the lateral surfaces of the substrate and across an entire thickness of the substrate, wherein each of the set of lateral conductive pads extends from the substrate to the mold cap to cover a portion of a thickness of the mold cap, and wherein the set of lateral conductive pads are electrically coupled to the embedded conductive wires of the substrate.

11. A semiconductor package assembly, comprising:
a base substrate;
a first semiconductor package having a first set of conductive pads and a second set of conductive pads on a first lateral surface and a second lateral surface of the first semiconductor package, respectively, wherein the first and second sets of conductive pads are electrically coupled with each other; wherein the first semiconductor package is mounted on the base substrate via the first set of conductive pads;
a second semiconductor package having a third set of conductive pads and a fourth set of conductive pads on a third lateral surface and a fourth lateral surface of the second semiconductor package, respectively, wherein the third and fourth sets of conductive pads are electrically coupled with each other; wherein the second semiconductor package is mounted on the first semiconductor package via the second and third sets of conductive pads; and
wherein the first and second semiconductor packages stand vertically with respect to the base substrate.
